(19) United States
(12) Patent Application Publication
(10) Pub. No.: US 2026/0332123 A1
(43) Pub. Date: Oct. 22, 2026

(54) FREQUENCY ALTERATION AND PERFORMANCE ENHANCEMENT OF A RESONANT MEMS DEVICE

(71) Applicant: UNIVERSITY OF SOUTH FLORIDA, Tampa, FL (US)

(72) Inventors: Ugur GUNEROGLU, Tampa, FL (US); Jing WANG, Tampa, FL (US); Adnan ZAMAN, Riyadh (SA)

(21) Appl. No.: 19/630,264

(22) Filed: Mar. 26, 2026

Related U.S. Application Data
(60) Provisional application No. 63/778,043, filed on Mar. 26, 2025.
(60) Provisional application No. 64/018,130, filed on Mar. 26, 2026.

(51) Int. Cl. H03H 9/02; H03H 9/24

(52) U.S. Cl. CPC H03H 9/02401; H03H 9/2436

(57) ABSTRACT

Provided herein are methods for post-fabrication frequency alteration and performance enhancement of a resonant microelectromechanical systems (MEMS) device. A first current is applied to a bottom electrode underlying a transducer layer of the MEMS device, the bottom electrode overlying a substrate material, to heat the bottom electrode above a first temperature threshold at which the bottom electrode material diffuses into the substrate material. After applying the first current, a second current is applied to the bottom electrode to heat the bottom electrode above a second temperature threshold, higher than the first temperature threshold, at which a metal-semiconductor compound forms between the bottom electrode material and the substrate material. Formation of the metal-semiconductor compound alters the stiffness and acoustic velocity of the resonator, enabling controlled trimming of the resonant frequency and enhancement of the quality factor.

### CROSS-REFERENCE TO RELATED APPLICATIONS

This application claims the benefit of U.S. Provisional Application Ser. No. 63/778,043, filed Mar. 26, 2025, and the benefit of U.S. Provisional Application Ser. No. 64/018,130, filed Mar. 26, 2026, the contents of which are hereby incorporated by reference in their entireties for all purposes.

### STATEMENT OF FEDERALLY SPONSORED RESEARCH

This invention was made with government support under Grant Nos. ECCS1711790 and ECCS2329207 awarded by the National Science Foundation (NSF), and Award No. HT9425-23-1-0502 awarded by the Defense Health Agency, Medical Research and Development Branch (DHA/MRDB). The government has certain rights in the invention.

### BACKGROUND

Microelectromechanical systems (MEMS) are devices that function on the micro-scale to provide mechanically- and electrically driven functionality to a wide variety of applications, including but not limited to timing, frequency filtering, sensing, and communication. For example, communication filters for channel/frequency band selectivity, oscillators, phased locked loop frequency synthesizers, and sensors for inertial measurement units (e.g., accelerometers and gyroscopes) may be enabled by MEMS-based resonance devices, many of which may necessitate precise resonant frequency control and a high quality factor (Q).

However, there may be technical reasons for a need in frequency shift, or trimming, of the devices. Unavoidable manufacturing tolerances in the form of geometric inaccuracies or fabrication imperfections may occur when the MEMS devices are constructed. For example, misalignment, over/under exposure in photolithography, exceeding the desired deposited thickness of materials during thin- or thick-film deposition steps, and inadequate or over etching of targeted thicknesses may be performed when the MEMS devices are fabricated.

Typically, manufacturers will attempt to perform post-fabrication trimming of the resonators after production by modifying a mass of the resonators during testing. For example, mass may be deposited onto the resonators to lower the frequency, or a laser may be used to punch a hole in the resonator when attempting to raise the frequency. These methods, however, risk lowering of the Q factor as a result of the introduction of new material or the removal of structurally critical parts.

### SUMMARY

A post-MEMS device fabrication technique for selective localized annealing is described herein. Broadly, such devices may undergo initial tests to determine a need for performance enhancement and/or frequency trimming. The methods described herein provide for an electrical current to be applied to the device through electrodes, which may cause a temperature of the device body to rise in a well-controlled fashion, inducing localized annealing and the generation of a metal-semiconductor compound through diffusion of a bottom electrode metal into an adjacent semiconductor layer.

In various instances, the MEMS device may also be on the nanoscale (NEMS device). It is contemplated that the described confinement of a heated thermal profile as well as transient response time for annealing in a confined region of the microsystem may be applicable to a wide range of building materials and substrates for such devices.

### BRIEF DESCRIPTION OF DRAWINGS

The figures described below, which form part of the present disclosure, are illustrative of embodiments described herein and are not meant to limit the scope of the disclosure in any manner.

FIG. 1 is a conceptual illustration of a fabrication process 100 for a thin-film piezoelectric-on-silicon (TPoS) MEMS resonator 102 under localized annealing that depicts how a DC current 116 may be applied through a layer structure of the resonator 102 to induce a localized Joule heating effect.

FIG. 2 displays a simplified step-by-step fabrication process flow 200, showing key fabrication steps of a TPoS MEMS resonator 202.

FIG. 3 displays a conceptual flow diagram 300 of silicide formation that occurs as a result of localized annealing.

FIG. 4 is a schematic diagram of an example method 400 of conducting repeatable localized annealing for frequency trimming.

FIG. 5A shows a top-view schematic 500 of a rectangular plate resonator with an interdigited electrode to depict the location for a focused ion beam (FIB) cut to retrieve a transmission electron microscopy (TEM) sample.

FIG. 5B shows a scanning electron microscopy (SEM) photo 502 taken during FIB to show the location of the sample of FIG. 5A cut from a device.

FIG. 5C shows a TEM image 504 of the investigated area of the localized annealed device of FIG. 5A across stacked layers.

FIGS. 6A and 6B show TEM images 600, 602 of specimens prepared by FIB and taken from unannealed rectangular plate resonators to analyze the interfaces between silicon, Cr, Pt, and ZnO layers.

FIGS. 6C-6E show TEM images 604-608 of specimens prepared by FIB and taken from annealed rectangular plate resonators to analyze the interfaces between silicon, Cr, Pt, and ZnO layers.

FIG. 7A displays measured transmission characteristics of a ZnO piezoelectric TPoS rectangular-plate resonator before and after each of five successive localized annealing runs (Run 1 through Run 5).

FIG. 7B displays annealing parameters applied during each of the five successive localized annealing runs of FIG. 7A, including applied current, applied average DC power, time of annealing, and energy dosage for each run.

### DETAILED DESCRIPTION

The detailed description set forth below in connection with the appended drawings is intended as a description of various configurations and is not intended to represent the only configurations in which the subject matter described herein may be practiced. The detailed description includes specific details to provide a thorough understanding of various embodiments of the present disclosure. However, it will be apparent to those skilled in the art that the various features, concepts and embodiments described herein may be implemented and practiced without these specific details. In some instances, well-known structures and components are shown in block diagram form to avoid obscuring such concepts.

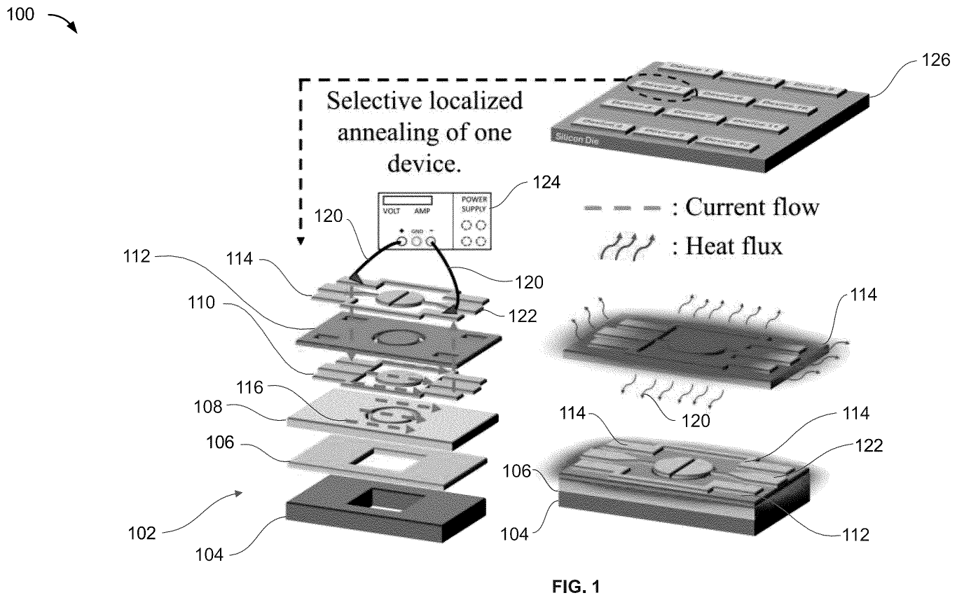

FIG. 1 displays how localized annealing may be performed on a MEMS resonator 102. In various instances, the MEMS resonator 102 may be provided in the form of a first layer 104, a second layer 106, a third layer 108, a fourth layer 110, a fifth layer 112, and a sixth layer 114. In other instances, the MEMS resonator 102 may be provided in the form of a greater or fewer number of layers than is described herein. A current 116 may be passed through the resonator 102, generating heat 118 inside the resonator 102.

In some instances, the heat 118 may be applied to a base of the resonator 102 via one or more terminals 120. In some such instances, the resonator 102 may be suspended during contact with the terminals 120, and one or more side supporting anchors 122 may be designed within the resonator 102 as to accept the terminals 120 and guide the heat 118 through the body of the resonator 102. The terminals 120 may be coupled to a power source 124. In some cases, the resonator 102 may be formed as part of a larger silicon die 126.

The side-supporting anchor structures 112 serve a dual function in the context of the localized annealing process. The anchors 112 provide their structural function of mechanically suspending the resonator body 110 relative to the substrate and of defining acoustic boundary conditions of the resonator. The anchors 112 also serve as the current path through which electrical current enters and exits the resonator body during localized annealing. Because the anchor structures 112 have a smaller cross-sectional area relative to the resonator body 110, the current density, and therefore the Joule heating intensity, tends to be elevated at the anchor regions. In various examples, simulation and experimental observation indicate that the anchor regions reach a higher local temperature during annealing than the resonator body, with both regions nonetheless undergoing elevated temperature and associated material changes. Microstructural changes in the anchor material following localized annealing may reduce anchor-related energy dissipation, contributing to the observed increase in Q factor. Energy dissipation through acoustic radiation from the resonator body into the substrate via the anchor structures is a recognized mechanism of Q reduction in MEMS resonators, and in various examples, annealing of the anchor structures may reduce this loss pathway, thereby contributing to Q improvement independently of the stiffening effect that shifts resonance frequency. In various examples, annealing conditions may be selected with consideration of the thermal and structural state of the anchor regions, in addition to the resonator body and electrode stack.

The side-supporting anchor structures 112 serve a dual function in the context of the localized annealing process. The anchors 112 provide their structural function of mechanically suspending the resonator body 110 relative to the substrate and of defining acoustic boundary conditions of the resonator. The anchors 112 also serve as the current path through which electrical current enters and exits the resonator body during localized annealing. Because the anchor structures 112 have a smaller cross-sectional area relative to the resonator body 110, the current density, and therefore the Joule heating intensity, tends to be elevated at the anchor regions. In various examples, simulation and experimental observation indicate that the anchor regions reach a higher local temperature during annealing than the resonator body, with both regions nonetheless undergoing elevated temperature and associated material changes. Microstructural changes in the anchor material following localized annealing may reduce anchor-related energy dissipation, contributing to the observed increase in Q factor. Energy dissipation through acoustic radiation from the resonator body into the substrate via the anchor structures is a recognized mechanism of Q reduction in MEMS resonators, and in various examples, annealing of the anchor structures may reduce this loss pathway, thereby contributing to Q improvement independently of the stiffening effect that shifts resonance frequency. In various examples, annealing conditions may be selected with consideration of the thermal and structural state of the anchor regions, in addition to the resonator body and electrode stack.

A frequency of the resonator 102 may be found using the principles of bulk acoustic wave (BAW) resonators and/or surface acoustic wave resonators, which vibrate acoustically and generate different electrical resonance responses at different harmonics/modes. A natural frequency (co) of the resonator 102 may be described by the mass (m) loading effect, represented by Equation 1, where k is the spring constant:

In various examples, the resonator 102 may be formed as part of a larger integrated device comprising an array of resonators disposed on a common substrate. The localized Joule-heating approach described herein allows trimming to be applied selectively to a single target resonator within such an array without substantially affecting adjacent resonators on the same die. Because thermal energy is generated within the target resonator through the current path defined by the electrodes and the resonator body, the resulting temperature elevation is localized and does not propagate substantially to neighboring devices. In various examples, while the targeted resonator reaches temperatures sufficient for platinum diffusion and silicide formation, adjacent resonators in the array may experience a temperature rise of less than approximately 20 degrees C. This degree of thermal selectivity is not achievable using furnace annealing, rapid thermal annealing, oven annealing, or hot-plate annealing processes, which expose the entire die and wafer to elevated temperatures uniformly. Accordingly, in various examples, each resonator in an array may be individually addressed and trimmed to a target frequency using the described process, enabling post-fabrication compensation of device-to-device frequency variation across the array. Finite-element simulation of an array of rectangular-plate resonators indicates that a target resonator reaching temperatures of approximately 1060 degrees C at its anchor regions may leave adjacent resonators at temperatures below approximately 70 degrees C.

In various examples, the resonator 102 may be formed as part of a larger integrated device comprising an array of resonators disposed on a common substrate. The localized Joule-heating approach described herein allows trimming to be applied selectively to a single target resonator within such an array without substantially affecting adjacent resonators on the same die. Because thermal energy is generated within the target resonator through the current path defined by the electrodes and the resonator body, the resulting temperature elevation is localized and does not propagate substantially to neighboring devices. In various examples, while the targeted resonator reaches temperatures sufficient for platinum diffusion and silicide formation, adjacent resonators in the array may experience a temperature rise of less than approximately 20 degrees C. This degree of thermal selectivity is not achievable using furnace annealing, rapid thermal annealing, oven annealing, or hot-plate annealing processes, which expose the entire die and wafer to elevated temperatures uniformly. Accordingly, in various examples, each resonator in an array may be individually addressed and trimmed to a target frequency using the described process, enabling post-fabrication compensation of device-to-device frequency variation across the array. Finite-element simulation of an array of rectangular-plate resonators indicates that a target resonator reaching temperatures of approximately 1060 degrees C at its anchor regions may leave adjacent resonators at temperatures below approximately 70 degrees C.

$$ω = \sqrt{\frac{k}{m}} \qquad ( 1 )$$

When the mass (m) increases, the frequency (w) may thus drift downwards. Thus, after fabrication, material may be deposited on a surface of resonator devices in order to create a mass loading effect and consequently lower frequency down to a desired frequency (frequently over 1 GHz). However, introduction of foreign material may risk a lowering of the Q factor of the device 102.

Without being bound by a particular theory, by conducting the current 116 through the resonator 102 body through the anchors 122, the heat 118 may elevate a temperature of the resonator 102 body, causing metal in the electrodes 114 of the resonator 102 to diffuse into the resonator body 102 and form a metal-semiconductor compound (e.g., a silicide or other compound), altering a stiffness of the material forming the structure of the resonator 102. For instance, the metal-semiconductor compound may comprise a compound formed by interdiffusion and reaction of a metal and a semiconductor material at or near the interface between those materials, including without limitation metal silicides such as platinum silicide (PtSi), platinum disilicide (Pt₂Si), and copper silicide (Cu₃Si), metal-semiconductor eutectic compounds such as Au—Si eutectic compounds, and Al—Si interface compounds. This change in stiffness, as measured by Young's modulus, may modify the acoustics of the resonator 102, leading to a frequency shift.

The localized annealing process can give rise to distinct phases of platinum silicide depending on the temperature reached at the platinum-silicon interface. In various examples, at temperatures of approximately 180 degrees C to 200 degrees C, platinum atoms begin to diffuse into the adjacent single-crystal silicon device layer and a first platinum silicide phase, Pt₂Si, begins to form. As the temperature rises further, to approximately 280 degrees C to 400 degrees C, silicon atoms diffuse within the growing silicide region and the Pt₂Si phase can transition to a second phase, PtSi. The PtSi phase is associated with an increase in Young's modulus relative to unreacted platinum or to Pt₂Si, and its formation is understood to be a contributor to the observed increase in resonance frequency of the device following localized annealing. In various examples, the annealing conditions, including applied power level, duration, and current waveform, may be selected to produce a desired phase or mixture of phases within the platinum-silicon interfacial region. Cross-sectional transmission electron microscopy (TEM) analysis of annealed devices has revealed the formation of a new interfacial phase at the platinum-silicon boundary consistent with PtSi, including crystallographic orientations consistent with the (101) and (021) planes of PtSi and characteristic lattice spacings of approximately 3.08 angstroms and 2.2 angstroms, respectively. Energy-dispersive X-ray spectroscopy (EDS) of cross-sectional specimens has confirmed that platinum diffuses into the single-crystal silicon device layer following localized annealing, with platinum detected at distances extending to approximately one micrometer from the original platinum-silicon interface.

In various examples, the localized annealing process is governed by three operating parameters that together define an annealing window within which effective trimming can be achieved. The first parameter is a minimum power level, or minimum applied current, below which insufficient diffusion or metal-semiconductor compound formation occurs and the resonance frequency does not shift. The second parameter is a minimum temperature at the metal-silicon interface below which diffusion and metal-semiconductor compound formation do not proceed to a degree that produces a measurable frequency shift. The third parameter is an upper temperature limit above which the resonator structure may be damaged, for example through excessive metal-semiconductor compound growth, de-adhesion of electrode layers, or fracture of the resonator body. In various examples, the annealing window may be characterized for a given resonator geometry and electrode stack by incrementally increasing applied power or duration and monitoring frequency shift and Q factor between successive annealing steps. The thermal budget, defined in some examples as the product of applied power and duration or as a cumulative energy dosage, may be used to characterize the total extent of metal-semiconductor compound formation across multiple sequential annealing runs. In various examples, successive short-duration annealing steps may be applied cumulatively, with frequency measured between steps, to provide incremental frequency trimming.

The localized annealing process can give rise to distinct phases of platinum silicide depending on the temperature reached at the platinum-silicon interface. In various examples, at temperatures of approximately 180 degrees C, platinum atoms begin to diffuse into the adjacent single-crystal silicon device layer and a first platinum silicide phase, Pt₂Si, begins to form. As the temperature rises further, to approximately 260 degrees C, this phase transitions predominantly into Pt₂Si. At approximately 360 degrees C, the PtSi phase starts to form. The PtSi phase is associated with an increase in Young's modulus relative to unreacted platinum or to Pt₂Si, and its formation is understood to be a contributor to the observed increase in resonance frequency of the device following localized annealing. In various examples, the annealing conditions, including applied power level, duration, and current waveform, may be selected to produce a desired phase or mixture of phases within the platinum-silicon interfacial region. Cross-sectional transmission electron microscopy (TEM) analysis of annealed devices has revealed the formation of a new interfacial phase at the platinum-silicon boundary consistent with PtSi, including crystallographic orientations consistent with the (101) and (021) planes of PtSi and characteristic lattice spacings of approximately 3.08 angstroms and 2.2 angstroms, respectively. Energy-dispersive X-ray spectroscopy (EDS) of cross-sectional specimens has confirmed that platinum diffuses into the single-crystal silicon device layer following localized annealing, with platinum detected at distances extending to approximately one micrometer from the original platinum-silicon interface.

In various examples, the localized annealing process is governed by three operating parameters that together define an annealing window within which effective trimming can be achieved. The first parameter is a minimum power level, or minimum applied current, below which no detectable diffusion or metal-semiconductor compound formation occurs and the resonance frequency does not shift. The second parameter is a minimum temperature at the platinum-silicon interface below which diffusion and metal-semiconductor compound formation do not proceed to a degree that produces a measurable frequency shift. The third parameter is an upper temperature limit above which the resonator structure may be damaged, for example through excessive metal-semiconductor compound growth, de-adhesion of electrode layers, or fracture of the resonator body. In various examples, the annealing window may be characterized for a given resonator geometry and electrode stack by incrementally increasing applied power or duration and monitoring frequency shift and Q factor between successive annealing steps. The thermal budget, defined in some examples as the product of applied power and duration or as a cumulative energy dosage, may be used to characterize the total extent of metal-semiconductor compound formation across multiple sequential annealing runs. In various examples, successive short-duration annealing steps may be applied cumulatively, with frequency measured between steps, to provide incremental frequency trimming.

The localized annealing process 100 may result from Joule heating. Localized annealing may thereby be used with a controlled dosage and time in order change a frequency of the MEMS resonator 102 in a chosen direction. In some instances, the Joule heating may be induced by a DC current 116. In other instances, the Joule heating may be induced by an AC current 116. In yet other instances, the Joule heating may be induced by a pulsed current 116. In some such instances, the Joule heating may be performed in an ambient gas environment.

In some instances, an amount of current 116 applied and a time duration of the current 116 may have an inverse relationship. For example, a thermal budget may be defined as a product of the thermal input and time of application of the current 116 to the resonator 102. An annealing effect of the resonator may thus be controlled by balancing an intensity of the current 116 applied and its application time. In some instances, the current 116 may be applied at an intensity of at least about 0.5 W, or at least about 1 W, or at least about 1.5 W, or at least about 2 W, or at least about 2.5 W, or at least about 3 W, or at least about 3.5 W, or at least about 4 W, or other suitable intensities. In other instances, a time duration may be at least about 1 second, or at least about 5 seconds, or at least about 10 seconds, or at least about 30 seconds, or at least about 1 minute, or at least about 5 minutes, or at least about 10 minutes, or at least about 30 minutes, or other suitable durations.

In some instances, localized annealing may improve a Q factor of the resonator 102. For example, as a result of Joule heating, the Q factor may increase by at least about 1%, or at least about 5%, or at least about 10%, or at least about 20%, or at least about 30%, or at least about 40%, or at least about 50%, or other suitable amounts.

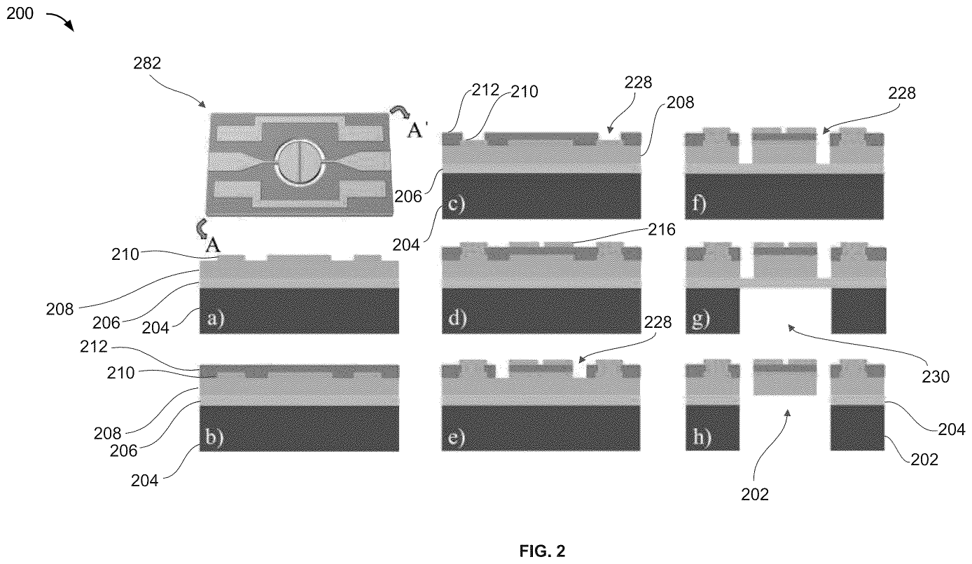

FIG. 2 displays an example fabrication process 200 in accordance with the present disclosure. The fabrication process 200 may produce a MEMS resonator 202, which may be substantially similar in form and function to the MEMS resonator 102, constructed in the form of a first layer 204, a second layer 206, a third layer 208, a fourth layer 210, a fifth layer 212, and a sixth layer 214. In some instances, the fabrication process 200 may include additional or fewer steps in order to construct the resonator 202, which may further include additional or fewer layers than as described herein.

In various instances, the first layer 204 may be provided in the form of a silicon handle substrate, and the second layer 206 may be provided in the form of a buried oxide layer. In some instances, one or more of the first layer 204 and the second layer 206 may be etched, such as by using a high-aspect-ratio (HAR) deep reactive ion etching process or a directional reactive ion etching process. In other instances, the buried oxide layer 206 may be an insulator, such as silicon dioxide.

In various instances, the third layer 208 may be provided in the form of a silicon device. The silicon device 208 may act as a source of silicon allowing for silicide formation within the resonator 202 upon localized annealing of the resonator 202. In some instances, the third layer 208 may be a pure silicon wafer. In other instances, the third layer 208 may be another source of silicon, such as silicon carbide. In yet other instances, the silicon source within the third layer 208 may be P- or N-doped.

In various instances, the fourth layer 210 may be provided in the form of one or more metals. For example, the fourth layer 210 may include platinum (Pt). In some instances, the fourth layer 210 may include, be substantially composed of, or be entirely composed of Pt. In some such instances, the fourth layer 210 may be composed of an alloy including both Pt and chromium (Cr). In other instances, the fourth layer 210 may include other metals, such as aluminum, gold, copper, and titanium.

The selection of electrode metal is relevant to the localized annealing process because the frequency trimming mechanism described herein depends on the ability of the electrode metal to diffuse into the adjacent silicon device layer at the temperatures reached during localized annealing. Platinum forms metal-semiconductor compounds (e.g., silicide phases such as Pt₂Si and PtSi) at moderate temperatures achievable by localized Joule heating. Other metals that exhibit diffusion into silicon at comparable temperatures may produce similar metal-semiconductor compound formation-based trimming effects. In various examples, gold and copper exhibit a pronounced tendency to diffuse into silicon and into adjacent thin-film layers at elevated temperatures, a property that has historically led to the use of diffusion barrier layers in thin-film fabrication processes to prevent unintended interdiffusion at interfaces. In the context of the localized annealing process described herein, this same diffusion tendency may be leveraged as a functional property to achieve controlled, localized modification of the resonator's material structure during trimming. In various examples, electrode stacks comprising titanium and platinum (Ti/Pt), or chromium and gold (Cr/Au), alongside the chromium and platinum (Cr/Pt) stack described above, may be used as the bottom electrode of the resonator and may undergo diffusion-mediated metal-semiconductor compound formation at the electrode-silicon interface during localized annealing. Aluminum also exhibits diffusion into silicon at elevated temperatures, though its diffusion characteristics at temperatures used in localized annealing may differ from those of platinum, gold, or copper. In various examples, the choice of electrode metal or electrode stack may be made with reference to the annealing window appropriate for that electrode system, which may differ from the annealing window described herein for the Cr/Pt system.

The selection of electrode metal is relevant to the localized annealing process because the frequency trimming mechanism described herein depends on the ability of the electrode metal to diffuse into the adjacent silicon device layer at the temperatures reached during localized annealing. Platinum forms metal-semiconductor compounds (e.g., silicide phases such as Pt₂Si and PtSi) at moderate temperatures achievable by localized Joule heating. Other metals that exhibit diffusion into silicon at comparable temperatures may produce similar metal-semiconductor compound formation-based trimming effects. In various examples, gold and copper exhibit a pronounced tendency to diffuse into silicon and into adjacent thin-film layers at elevated temperatures, a property that has historically led to the use of diffusion barrier layers in thin-film fabrication processes to prevent unintended interdiffusion at interfaces. In the context of the localized annealing process described herein, this same diffusion tendency may be leveraged as a functional property to achieve controlled, localized modification of the resonator's material structure during trimming. In various examples, electrode stacks comprising titanium and platinum (Ti/Pt), or chromium and gold (Cr/Au), alongside the chromium and platinum (Cr/Pt) stack described above, may be used as the bottom electrode of the resonator and may undergo diffusion-mediated metal-semiconductor compound formation at the electrode-silicon interface during localized annealing. Aluminum also exhibits diffusion into silicon at elevated temperatures, though its diffusion characteristics at temperatures used in localized annealing may differ from those of platinum, gold, or copper. In various examples, the choice of electrode metal or electrode stack may be made with reference to the annealing window appropriate for that electrode system, which may differ from the annealing window described herein for the Cr/Pt system.

In some instances, the fourth layer 210 may cover at least about 20% of a surface area of a top end of the third layer 208. For example, the fourth layer 210 may cover at least about 20%, or at least about 30%, or at least about 40%, or at least about 50%, or at least about 60%, or at least about 70%, or at least about 80%, or at least about 90%, or at least about 99% of a surface area of a top end of the third layer 208. The metal, such as Pt, in the fourth layer 210 may be designed to diffuse into the silicon of the third layer 208 to form a metal-semiconductor compound (e.g., a silicide or other compound) upon heating.

In various instances, the fifth layer 212 may include zinc oxide (ZnO). For example, the fifth layer 212 may include, be substantially composed of, or be entirely composed of ZnO. In some instances, the fifth layer 212 may be a piezoelectric material. In some such instances, the zinc oxide in the fifth layer 212 may be sensitive to a localized annealing temperature range. For example, the fifth layer 212 may be sensitive to localized annealing at temperatures of at least about 300 °C, or at least about 320 °C, or at least about 340 °C, or at least about 360 °C, or at least about 380 °C, or at least about 400 °C. In other instances, the fifth layer 212 may be deposited on the resonator 202 via a sputtering process. In some such instances, the fifth layer 212 may be deposited using pulsed deposition in a vacuum chamber.

In various examples, the fifth layer 212 may function as a transducer layer that converts between electrical energy and mechanical energy. For instance, the transducer layer may comprise a piezoelectric material, such as zinc oxide (ZnO), aluminum nitride (AlN), scandium-doped aluminum nitride (ScAlN), lead zirconate titanate (PZT), or lithium niobate, or other electromechanically active materials suitable for use in MEMS resonator structures. In other examples, the transducer layer may comprise a capacitively driven or electrostatically actuated layer, such as a conductive plate or membrane separated from a drive electrode by a narrow electrostatic gap, in which case the transducer layer converts between electrical and mechanical energy via electrostatic force rather than piezoelectric coupling. In further examples, the transducer layer may comprise a piezoresistive material, in which mechanical strain in the transducer layer modulates its electrical resistance, permitting detection of mechanical resonance via resistance measurement. In yet further examples, the transducer layer may comprise a magnetostrictive material, in which coupling between magnetic and mechanical domains enables electromechanical transduction.

While zinc oxide is described above as one example of a piezoelectric material suitable for the fifth layer 120, the fifth layer 120 is not limited to zinc oxide. In various examples, the fifth layer 120 may comprise any piezoelectric material that is compatible with the resonator stack and the localized annealing process described herein. Alternative piezoelectric materials suitable for the fifth layer 120 include aluminum nitride (AlN); scandium-doped aluminum nitride (Sc—AlN), which exhibits enhanced piezoelectric coupling relative to undoped AlN and may be deposited by reactive sputtering with a scandium-doped aluminum target; lead zirconate titanate (PZT), a ferroelectric perovskite material with high piezoelectric coefficients; lithium niobate (LiNbO₃); or other suitable piezoelectric thin-film materials. Lithium niobate is a single-crystal piezoelectric material with well-characterized electromechanical coupling coefficients and is used in bulk acoustic wave and surface acoustic wave resonator technologies. In various examples, lithium niobate may be incorporated into the resonator stack as a thin film, for example by wafer bonding and thinning of a lithium niobate layer, and oriented to provide a desired piezoelectric coupling mode (e.g., thickness-extensional or lateral-extensional coupling). The selection among these alternative piezoelectric materials may be based on one or more of the piezoelectric coupling coefficient for the desired resonance mode, compatibility with the electrode materials in the stack, thermal stability under the localized annealing conditions, achievable film quality, or compatibility with the fabrication process. The localized annealing process described herein is applicable to resonators employing any of the foregoing piezoelectric materials, where the annealing conditions are selected with reference to the annealing window appropriate for the electrode and piezoelectric materials used.

While zinc oxide is described above as one example of a piezoelectric material suitable for the fifth layer 120, the fifth layer 120 is not limited to zinc oxide. In various examples, the fifth layer 120 may comprise any piezoelectric material that is compatible with the resonator stack and the localized annealing process described herein. Alternative piezoelectric materials suitable for the fifth layer 120 include aluminum nitride (AlN); scandium-doped aluminum nitride (Sc—AlN), which exhibits enhanced piezoelectric coupling relative to undoped AlN and may be deposited by reactive sputtering with a scandium-doped aluminum target; lead zirconate titanate (PZT), a ferroelectric perovskite material with high piezoelectric coefficients; lithium niobate (LiNbO₃); or other suitable piezoelectric thin-film materials. Lithium niobate is a single-crystal piezoelectric material with well-characterized electromechanical coupling coefficients and is used in bulk acoustic wave and surface acoustic wave resonator technologies. In various examples, lithium niobate may be incorporated into the resonator stack as a thin film, for example by wafer bonding and thinning of a lithium niobate layer, and oriented to provide a desired piezoelectric coupling mode (e.g., thickness-extensional or lateral-extensional coupling). The selection among these alternative piezoelectric materials may be based on one or more of the piezoelectric coupling coefficient for the desired resonance mode, compatibility with the electrode materials in the stack, thermal stability under the localized annealing conditions, achievable film quality, or compatibility with the fabrication process. The localized annealing process described herein is applicable to resonators employing any of the foregoing piezoelectric materials, where the annealing conditions are selected with reference to the annealing window appropriate for the electrode and piezoelectric materials used.

In some cases, the resonator 202 may undergo annealing in oxygen-depleted conditions. For example, the resonator 202 may be surrounded by an inert gas, such as nitrogen or argon, during localized annealing in order to minimize reactions between zinc and atmospheric oxygen, preserving a high conductivity of a zinc-rich ZnO fifth layer 212. In other cases, the fifth layer 212 may be deliberately exposed to oxygen in order to encourage filling of vacancies in pure ZnO. In some such cases, a fifth layer 212 including more oxygen may exhibit reduced stress, better crystal structure, and superior piezoelectric conduction compared to pure ZnO. In yet other cases, the fifth layer 212 may be deliberately exposed to a reducing environment, such as hydrogen gas, to remove oxygen from the ZnO layer 212.

In various examples, the piezoelectric layer, such as a ZnO layer, undergoes changes during the localized annealing process in addition to the platinum-silicon interfacial changes described above. Sputtered ZnO thin films as deposited may contain oxygen vacancies and point defects that reduce piezoelectric response and increase electrical conductivity of the film. The temperatures reached during localized annealing, which may fall within or exceed the temperature range employed for post-deposition annealing of sputtered ZnO films (approximately 300 degrees C to 400 degrees C), can be sufficient to promote reduction of oxygen vacancy concentration, improvement of crystalline texture, and reduction of residual film stress within the ZnO layer. Where the annealing is performed in an oxygen-containing ambient, oxygen atoms may diffuse into the ZnO layer and fill existing oxygen vacancies, thereby reducing undesired electrical conductivity of the ZnO layer and improving the piezoelectric coupling coefficient of the layer. In various examples, this results in an improvement in piezoelectric transduction efficiency of the device following localized annealing, manifested as a reduction in motional resistance and an improvement in insertion loss, alongside the frequency and Q factor changes attributable to metal-semiconductor compound formation.

In various examples where annealing is performed in an oxygen-depleted environment, such as a vacuum, an inert gas (e.g., nitrogen or argon), or a reducing gas mixture such as forming gas (e.g., a mixture of hydrogen and nitrogen), the ZnO layer may not undergo oxygen vacancy filling, and the stoichiometry and conductivity of the ZnO layer may differ from the outcome observed in an oxygen-rich environment. The choice of annealing ambient accordingly provides an additional degree of process control over the post-anneal properties of the piezoelectric layer. In various examples, the annealing ambient may be selected to address both the silicide formation process at the platinum-silicon interface and the oxygen stoichiometry of the ZnO layer.

In various examples, the chromium-containing layer serving as an adhesion layer between the silicon substrate and the platinum electrode layer may also undergo changes during the localized annealing process. Changes in the microstructure or interfacial chemistry of the chromium layer may occur following localized annealing and may include grain growth, interdiffusion with adjacent layers, or changes in oxidation state depending on the annealing ambient. The contribution of chromium layer changes to the overall change in resonator performance has not been fully characterized in all example configurations, and may affect interfacial adhesion, electrical contact resistance, or acoustic loss at the chromium-platinum or chromium-silicon interface. The description of material changes resulting from localized annealing encompasses changes in the chromium adhesion layer alongside the metal-semiconductor compound formation described herein.

In various examples, the piezoelectric layer, such as a ZnO layer, undergoes changes during the localized annealing process in addition to the platinum-silicon interfacial changes described above. Sputtered ZnO thin films as deposited may contain oxygen vacancies and point defects that reduce piezoelectric response and increase electrical conductivity of the film. The temperatures reached during localized annealing, which may fall within or exceed the temperature range employed for post-deposition annealing of sputtered ZnO films (approximately 300 degrees C to 400 degrees C), can be sufficient to promote reduction of oxygen vacancy concentration, improvement of crystalline texture, and reduction of residual film stress within the ZnO layer. Where the annealing is performed in an oxygen-containing ambient, oxygen atoms may diffuse into the ZnO layer and fill existing oxygen vacancies, thereby reducing undesired electrical conductivity of the ZnO layer and improving the piezoelectric coupling coefficient of the layer. In various examples, this results in an improvement in piezoelectric transduction efficiency of the device following localized annealing, manifested as a reduction in motional resistance and an improvement in insertion loss, alongside the frequency and Q factor changes attributable to metal-semiconductor compound formation.

In various examples where annealing is performed in an oxygen-depleted environment, such as a vacuum, an inert gas (e.g., nitrogen or argon), or a reducing gas mixture such as forming gas (e.g., a mixture of hydrogen and nitrogen), the ZnO layer may not undergo oxygen vacancy filling, and the stoichiometry and conductivity of the ZnO layer may differ from the outcome observed in an oxygen-rich environment. The choice of annealing ambient accordingly provides an additional degree of process control over the post-anneal properties of the piezoelectric layer. In various examples, the annealing ambient may be selected to address both the silicide formation process at the platinum-silicon interface and the oxygen stoichiometry of the ZnO layer.

In various examples, the chromium-containing layer serving as an adhesion layer between the silicon substrate and the platinum electrode layer may also undergo changes during the localized annealing process. Changes in the microstructure or interfacial chemistry of the chromium layer may occur following localized annealing and may include grain growth, interdiffusion with adjacent layers, or changes in oxidation state depending on the annealing ambient. The contribution of chromium layer changes to the overall change in resonator performance has not been fully characterized in all example configurations, and may affect interfacial adhesion, electrical contact resistance, or acoustic loss at the chromium-platinum or chromium-silicon interface. The description of material changes resulting from localized annealing encompasses changes in the chromium adhesion layer alongside the metal-semiconductor compound formation described herein.

In various instances, the sixth layer 214 may function as a set of electrodes for the resonator 202. In some instances, the sixth layer 214 may be provided in the form of split-top electrodes. In other instances, the sixth layer 214 may be composed of, substantially composed of, or entirely composed of the material of the fourth layer 210.

The fabrication process 200 displayed in FIG. 2 proceeds using a five-mask lithography process designed for silicon-on-insulator (SOI) wafers. In the example shown, the first layer 204 is a heavily p-type doped, 10-μm-thick silicon device layer. The fabrication starts with a dual-layer photolithography step to establish the third layer 208, after which Pt is sputtered and patterned via lift-off to form the bottom electrodes of the fourth layer 210. The fifth layer 212 of ZnO is added via reactive sputtering, and a ZnO wet etch then creates vias 228 for ground interconnections. A second dual-layer photolithography is then performed to define the top electrodes of the sixth layer 216, which are realized by sputtering Pt and patterning via lift-off.

After shaping the body of the resonator 202, the third and fourth layers 208, 210 are etched in a specialized reactive-ion etch (RIE) process at room temperature to precisely define the resonator 202 structure, after which the resonator 202 is covered with photoresist for protection and lithography/deep RIE is performed to open release holes 230 to suspend the resonator 202 and form release cavities. The completed disk resonator 202 of FIG. 2 thus features a pair of split-top electrodes. In some instances, the resonator 202 produced by the process 200 may exhibit lower motional resistance and higher quality factors, and may be tunable with localized annealing for frequency trimming.

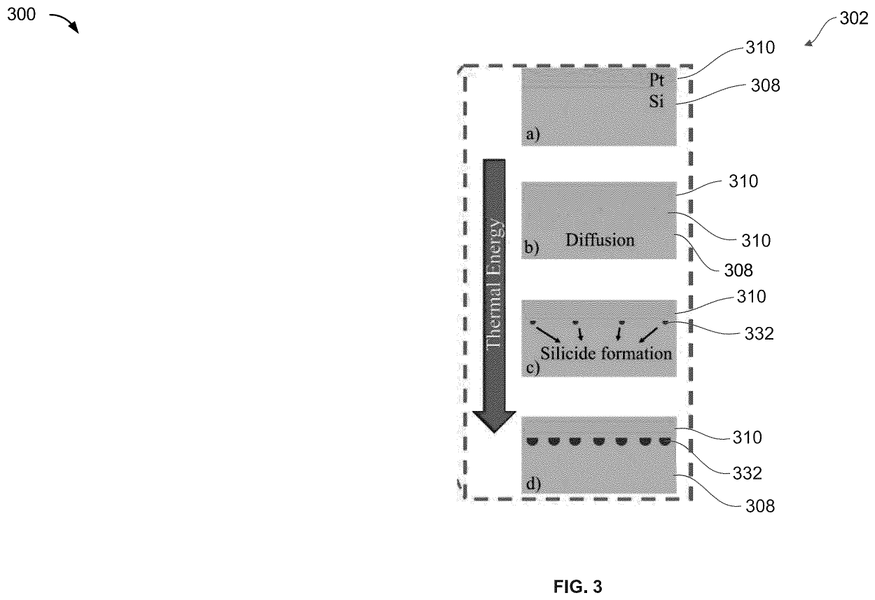

FIG. 3 illustrates the formation of silicide 332 as a result of metal diffusion from a fourth layer 310 of a resonator 302 into the silica-containing third layer 308, as thermal energy decreases. As shown, platinum may migrate downward through the resonator 302, interacting with internal silicon molecules to form particulates of silicide 332, enhancing a stiffness of the silicon-containing layer 308.

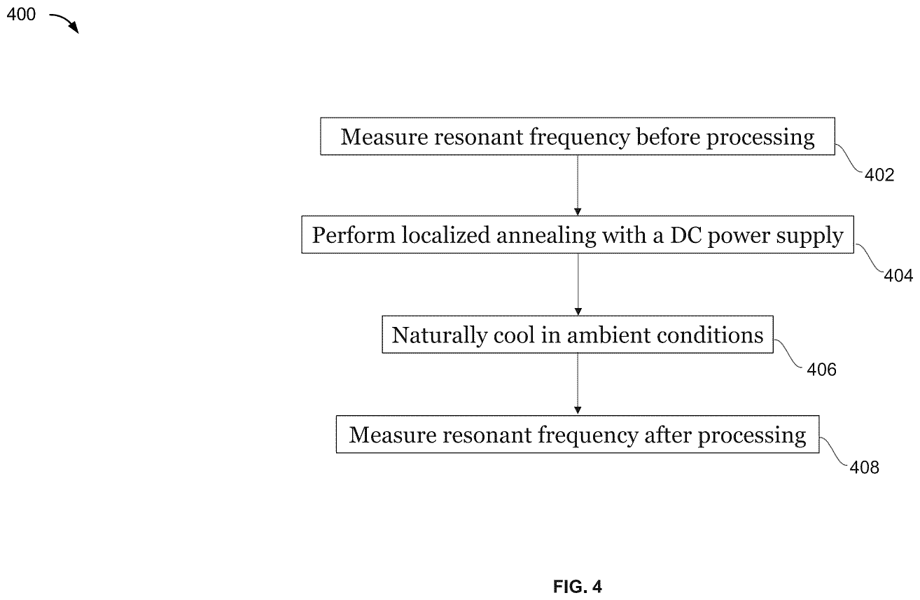

FIG. 4 is an example method 400 of a complete cycle of annealing (or a “run”) that may be repeated in a controlled fashion to shift a frequency of a resonator toward a desired resonant frequency. By performing the method 400 as many times as needed, the frequency may be trimmed in a predictable manner, and a Q factor of the resonator may improve while signal strength, performance, and impedance loss may also be affected. The trimming performed by the method 400 may produce a substantially permanent change in one or more characteristics of the resonator, such as its resonance frequency or quality factor, by inducing a compositional or microstructural change in one or more constituent layers of the resonator. Because the underlying change is structural and material in nature, the altered characteristic does not revert to its pre-trimming value upon removal of the energy input, such as upon cooling to ambient temperature. The trimming process is accordingly distinct from reversible frequency-temperature effects in acoustic resonator technology, in which a device's resonance frequency shifts in response to a change in operating temperature across a given temperature range but returns to substantially its original value when the temperature stimulus is removed. The localized annealing process induces diffusion and metal-semiconductor compound formation (e.g., silicides or other compounds) that alter the elastic properties of the resonator, such that the frequency shift is retained at subsequent operating temperatures. In various examples, the trimming process may be used together with a separate reversible tuning mechanism to provide both a coarse permanent adjustment and a fine dynamic adjustment of resonance frequency.

At 402, an initial resonant frequency fₒ of the resonator may be measured before processing of the resonator for use in downstream applications. In various instances, the initial resonant frequency fₒ may be unequal to a desired resonant frequency of the resonator, resulting in a need for a physical modification to be made to the resonator before use.

At 404, localized annealing may be performed on the resonator by applying a DC current to the resonator at a bottom of the device using one or more electrodes. Heat may thus be generated within the resonator according to the thermal energy equation shown in Equation 2, where t is time and Pₐₙₙₑₐₗ is applied power:

Qₜₕₑᵣₘₐₗ=Pₐₙₙₑₐₗ*t (2)

The thermal energy may cause a temperature of the resonator to increase both in the anchor supports of the resonator as well as the body of the resonator, resulting in platinum located at a top surface of the resonator to diffuse down to the silicon layers and form silicide. The applied power and time may thus be selected in accordance with preferred conditions in order to achieve a desired diffusion effect. The formation of silicide may cause the alteration of an effective stiffness (Young modulus E) of the resonator after the resonator cools to room temperature, which may alter a strain through the anchors and resonator body, also resulting in a change in acoustic velocity and trimming of the resonant frequency, as is mathematically described in Equations 3-5:

$${f}_{o} = \frac{α}{{R}_{disk}} {v}_{eq} \qquad ( 3 )$$

$${f}_{n} = \frac{n}{2 w} {v}_{eq} \qquad ( 4 )$$

$${v}_{eq} = \sqrt{\frac{{E}_{te} {T}_{te} + {E}_{p} {T}_{p} + {E}_{be} {T}_{be} + {E}_{dev} {T}_{dev}}{( {ρ}_{te} {T}_{te} + {ρ}_{p} {T}_{p} + {ρ}_{be} {T}_{be} + {ρ}_{dev} {T}_{dev} ) ( 1 - {μ}^{2} )}} \qquad ( 5 )$$

Higher stiffness may additionally elevate a Q factor associated with the resonator as shown in Equation 6, where the MEMS resonator is represented as a mass-spring system:

$$Q = \frac{\sqrt{mk}}{c} \qquad ( 6 )$$

Hence, increasing the spring constant k may make the behavior of the MEMS system more elastic, increasing Q as a result.

At 406, the resonator may cool in ambient conditions to room temperature before the resonant frequency is checked again at 408 after processing. In some cases, one or more steps of the method 400 may be repeated more than once, performed out-of-order, or omitted. In some instances, the method 400 may be repeated under varying conditions, such as those providing an increased or a decreased thermal energy to the resonator, in order to modify a frequency of the resonator by a different amount in subsequent runs. In other instances, the method 400 may be repeated under identical conditions (for example, the same thermal energy input) in order to modify a frequency of the resonator by a controlled amount in subsequent runs. In yet other instances, the method 400 may be repeated under changed conditions (for example, higher power for a shorter time or lower power for a longer time) in order to modify a frequency of the resonator by a controlled amount in subsequent runs.

In various examples, the localized Joule-heating trimming process described herein is compatible with automated or semi-automated wafer-level processing. Because the trimming process is performed by applying a controlled direct current to the existing electrode contacts of the resonator using, for example, a source meter or precision current source connected to a probe station, no additional specialized tooling beyond standard electrical probing equipment is used. In various examples, a pre-trim measurement of the resonator's resonance frequency and Q factor may be performed at the probe station, and the measured pre-trim frequency deviation from a target frequency may be used to determine an annealing recipe specifying applied current, total energy dosage, and duration sufficient to achieve the desired frequency shift. The annealing recipe may then be executed by the probing system without requiring per-device operator intervention. In various examples, an automated probing system may be programmed to sequentially address each resonator in an array, measure the pre-trim frequency, execute the appropriate trim recipe, and verify the post-trim frequency, enabling closed-loop frequency trimming at the wafer scale. In various examples, the applied current during localized annealing ranges from approximately 5 mA to approximately 15 mA, and the duration of each annealing step ranges from approximately 30 seconds to approximately 2 minutes, with specific values selected based on resonator geometry, electrode stack, and desired frequency shift. In various examples, trimming may be performed using a series of successive short-duration annealing pulses, with frequency verification between pulses, to achieve incremental and tightly controlled frequency correction.

In various examples, the temperature of the resonator during localized annealing may be monitored to verify that the annealing process remains within the desired annealing window. Temperature monitoring during localized annealing may be implemented using a variety of techniques. In various examples, an infrared (IR) microscope may be used to capture a thermal image of the resonator and surrounding die area during the annealing process, providing a spatially resolved map of surface temperature that can confirm the degree of thermal localization to the target device. Infrared microscopes suitable for this purpose may have a spatial resolution on the order of approximately 20 micrometers, which is sufficient to observe the thermal profile across the resonator body and adjacent devices but may not fully resolve the temperature at individual anchor structures having lateral dimensions on the order of approximately 5 micrometers. In various examples, a thermocouple, resistance temperature detector (RTD), or other contact temperature sensor may be positioned in proximity to the target resonator or die as a supplementary or alternative temperature measurement. In various examples, the local temperature at the resonator may be estimated from the applied power and a calibrated thermal resistance model of the device. In various examples, higher-resolution thermal imaging or on-chip temperature sensors may be employed to provide more spatially precise temperature monitoring at the anchor and body regions independently.

In various examples, the localized Joule-heating trimming process described herein is compatible with automated or semi-automated wafer-level processing. Because the trimming process is performed by applying a controlled direct current to the existing electrode contacts of the resonator using, for example, a source meter or precision current source connected to a probe station, no additional specialized tooling beyond standard electrical probing equipment is used. In various examples, a pre-trim measurement of the resonator's resonance frequency and Q factor may be performed at the probe station, and the measured pre-trim frequency deviation from a target frequency may be used to determine an annealing recipe specifying applied current, total energy dosage, and duration sufficient to achieve the desired frequency shift. The annealing recipe may then be executed by the probing system without requiring per-device operator intervention. In various examples, an automated probing system may be programmed to sequentially address each resonator in an array, measure the pre-trim frequency, execute the appropriate trim recipe, and verify the post-trim frequency, enabling closed-loop frequency trimming at the wafer scale. In various examples, the applied current during localized annealing ranges from approximately 5 mA to approximately 15 mA, and the duration of each annealing step ranges from approximately 30 seconds to approximately 2 minutes, with specific values selected based on resonator geometry, electrode stack, and desired frequency shift. In various examples, trimming may be performed using a series of successive short-duration annealing pulses, with frequency verification between pulses, to achieve incremental and tightly controlled frequency correction.

In various examples, the temperature of the resonator during localized annealing may be monitored to verify that the annealing process remains within the desired annealing window. Temperature monitoring during localized annealing may be implemented using a variety of techniques. In various examples, an infrared (IR) microscope may be used to capture a thermal image of the resonator and surrounding die area during the annealing process, providing a spatially resolved map of surface temperature that can confirm the degree of thermal localization to the target device. Infrared microscopes suitable for this purpose may have a spatial resolution on the order of approximately 20 micrometers, which is sufficient to observe the thermal profile across the resonator body and adjacent devices but may not fully resolve the temperature at individual anchor structures having lateral dimensions on the order of approximately 5 micrometers. In various examples, a thermocouple, resistance temperature detector (RTD), or other contact temperature sensor may be positioned in proximity to the target resonator or die as a supplementary or alternative temperature measurement. In various examples, the local temperature at the resonator may be estimated from the applied power and a calibrated thermal resistance model of the device. In various examples, higher-resolution thermal imaging or on-chip temperature sensors may be employed to provide more spatially precise temperature monitoring at the anchor and body regions independently.

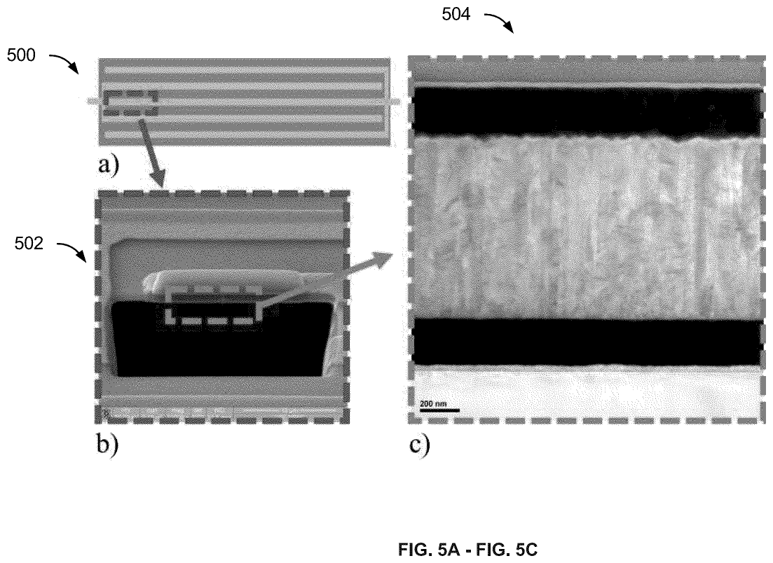

The TEM images 502, 504 of the rendered image 500 shown in FIGS. 5A-5C indicate successful localized annealing through Joule heating induced by a DC current under an ambient gas environment, where varied energy dosages have induced silicide formation through platinum (Pt) diffusion to a silicon (Si) layer.

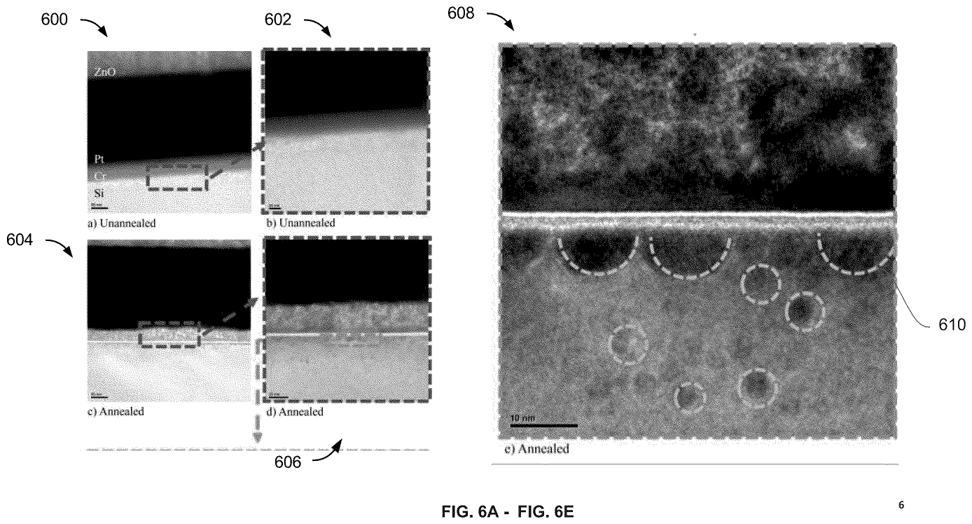

The TEM images 600-608 displayed in FIGS. 6A-6E demonstrate how localized annealing induced Pt—Si silicide formation, which in turn changed acoustic velocity and acoustic energy dissipation. As a result, frequency trimming and Q enhancement effects were consistently observed. In addition, the dark circular areas 610 shown in the silicon layer display the formation of silicide, where larger agglomerates of material are disposed under a top layer of the resonator while smaller, localized crystals are diffused lower into the body of the resonator, having diameters between about 2 nm and about 5 nm.

In various examples, cross-sectional specimens for TEM analysis may be prepared using a focused ion beam (FIB) tool, which allows site-specific thinning of the resonator stack to electron transparency (e.g., to a thickness of approximately 100 nm) at a selected location, such as at the platinum-silicon interface in a region of the resonator body or anchor. TEM images of cross-sectional specimens obtained before and after localized annealing reveal the formation of a new interfacial phase at the platinum-silicon boundary consistent with platinum silicide, which appears as a region of altered contrast relative to the surrounding crystalline silicon and platinum layers. In various examples, selected-area electron diffraction (SAED) or fast Fourier transform (FFT) analysis of high-resolution TEM images confirms the crystallographic nature of the silicide phase, including lattice spacings and orientations consistent with PtSi (e.g., orientations consistent with the (101) and (021) planes of PtSi, with characteristic d-spacings of approximately 3.08 angstroms and 2.2 angstroms, respectively). EDS performed on cross-sectional specimens before and after localized annealing provides direct compositional evidence of platinum diffusion into the silicon device layer. In various examples, EDS line scans or maps across the platinum-silicon interface in the annealed specimen show a detectable platinum signal extending into the silicon device layer to distances of approximately one micrometer or more from the original platinum-silicon interface, confirming that localized annealing promotes platinum diffusion alongside surface-proximate silicide formation.

In various examples, cross-sectional specimens for TEM analysis may be prepared using a focused ion beam (FIB) tool, which allows site-specific thinning of the resonator stack to electron transparency (e.g., to a thickness of approximately 100 nm) at a selected location, such as at the platinum-silicon interface in a region of the resonator body or anchor. TEM images of cross-sectional specimens obtained before and after localized annealing reveal the formation of a new interfacial phase at the platinum-silicon boundary consistent with platinum silicide, which appears as a region of altered contrast relative to the surrounding crystalline silicon and platinum layers. In various examples, selected-area electron diffraction (SAED) or fast Fourier transform (FFT) analysis of high-resolution TEM images confirms the crystallographic nature of the silicide phase, including lattice spacings and orientations consistent with PtSi (e.g., orientations consistent with the (101) and (021) planes of PtSi, with characteristic d-spacings of approximately 3.08 angstroms and 2.2 angstroms, respectively). EDS performed on cross-sectional specimens before and after localized annealing provides direct compositional evidence of platinum diffusion into the silicon device layer. In various examples, EDS line scans or maps across the platinum-silicon interface in the annealed specimen show a detectable platinum signal extending into the silicon device layer to distances of approximately one micrometer or more from the original platinum-silicon interface, confirming that localized annealing promotes platinum diffusion alongside surface-proximate silicide formation.

Without being bound by a particular theory, it is thus contemplated that metal-semiconductor compound formation is a time-limited process, where a higher dosage and time applied to the resonator pushes the compound formation regions deeper through the thickness of the resonator, changing material properties of the system. Hence, as more annealing runs are applied, frequency may be expected to shift gradually and consistently.

In various examples, a first current may be applied to a bottom electrode of a resonant MEMS device, the bottom electrode overlying a substrate material, to resistively heat the bottom electrode above a first temperature threshold at which the bottom electrode material begins to diffuse into the substrate material. After applying the first current, a second current may be applied to the bottom electrode to heat the bottom electrode above a second temperature threshold, higher than the first temperature threshold, at which a metal-semiconductor compound forms at or near the interface between the bottom electrode and the substrate material. The first and second currents may be delivered using any of a variety of current delivery profiles, non-limiting examples of which are described below.

In some examples, a continuously increasing current may be applied to the bottom electrode, causing the temperature of the bottom electrode to rise in a continuous fashion. As the temperature rises above the first temperature threshold, diffusion of the bottom electrode material into the substrate material may commence. As the temperature continues to rise above the second temperature threshold, a metal-semiconductor compound may form at or near the electrode-substrate interface. In such examples, the portion of the current applied before the second temperature threshold is crossed may correspond to the first current, and the portion applied at and above that threshold may correspond to the second current.

In other examples, the bottom electrode may be heated using a pulsed current applied in a plurality of duty cycles. A first sequence of pulses may be applied at a selected duty cycle for a cumulative duration sufficient to raise the bottom electrode temperature above the first temperature threshold. A second sequence of pulses, at a different duty cycle or current magnitude, may then be applied to cumulatively drive the bottom electrode temperature above the second temperature threshold. The Joule heating power P=V×I may be monitored during each pulse, and the total thermal budget P×t may be tracked to manage the temperature profile and the extent of compound formation.

In further examples, a first current may be applied to raise the bottom electrode temperature above the first temperature threshold, after which the current may be reduced or terminated to allow the bottom electrode to partially cool. A second current may then be applied to raise the bottom electrode temperature above the second temperature threshold. This protocol may allow the diffusion phase and the compound formation phase to be controlled independently.

In various examples, the first current and the second current may each be direct currents (DC). In other examples, the first current and the second current may be alternating currents (AC), stepped currents, or other waveforms that deliver sufficient thermal energy to cause the bottom electrode temperature to cross the respective temperature thresholds. In some examples, a stepped current protocol may be used, in which a first current level is applied until the bottom electrode reaches or exceeds the first temperature threshold, and a second, higher current level is then applied to drive the temperature above the second temperature threshold.

In various examples, one or more resonance parameters of the resonant MEMS device may be measured during a testing operation after the second current has been applied and the device has been allowed to cool. The resonance parameter may be one or more of: a quality factor (Q) of the resonant MEMS device, a center frequency of the resonant MEMS device, a motional resistance of the resonant MEMS device, or an insertion loss of the resonant MEMS device. Each of these parameters may be measured using RF characterization equipment, such as a vector network analyzer or impedance analyzer, interfaced with functional contacts of the resonant MEMS device. For instance, the functional contacts may comprise electrical contacts on the resonant MEMS device through which electrical signals may be applied to or measured from the device during device operation or characterization, including contacts used to apply drive signals or to measure resonance parameters. If the measured resonance parameter does not satisfy a resonance evaluation condition, a further annealing cycle may be performed by applying a third current to the bottom electrode to heat the bottom electrode above the first temperature threshold, and then applying a fourth current to heat the bottom electrode above the second temperature threshold, following the same sequential protocol as the first and second currents. For instance, the resonance evaluation condition may comprise a criterion or set of criteria specifying a target or acceptable range for one or more resonance parameters of the resonant MEMS device, non-limiting examples of which include a center frequency within a specified tolerance, a quality factor (Q) above a threshold value, a motional resistance below a threshold value, or an insertion loss within a specified range. The measuring and re-annealing steps may be repeated in successive cycles until the resonance parameter satisfies the resonance evaluation condition.

In one example, a resonant MEMS device comprising a ZnO transducer layer and a platinum bottom electrode on a silicon substrate was subjected to a first annealing cycle by applying a first DC current and a second DC current in sequence through the functional contacts of the device. After the device cooled to room temperature, the center frequency was measured using a vector network analyzer. The measured center frequency did not satisfy the resonance evaluation condition, which was defined as a target frequency within a specified tolerance of the desired resonant frequency. A second annealing cycle was performed by applying a third DC current and a fourth DC current in the same sequential pattern. After cooling, the center frequency was measured again. The measured center frequency satisfied the resonance evaluation condition, and no further annealing cycles were performed.

In various examples, the substrate material may be a silicon device layer of a silicon-on-insulator (SOI) wafer. In some such examples, the SOI wafer may comprise, from bottom to top, a silicon handle wafer, a buried oxide (BOX) layer above the silicon handle wafer, and a silicon device layer above the buried oxide layer. The bottom electrode may overlie the silicon device layer, with the transducer layer disposed above the bottom electrode. The buried oxide layer may provide electrical isolation between the silicon device layer and the silicon handle wafer. The silicon device layer may serve as a semiconductor source material for metal-semiconductor compound formation when the bottom electrode material diffuses into the silicon device layer upon application of the first and second currents.

In various examples, the bottom electrode may comprise platinum (Pt). When platinum is heated above approximately 180 degrees C in contact with a silicon substrate material, platinum may diffuse into the silicon and an initial platinum silicide phase, Pt₂Si, may begin to form at the electrode-substrate interface. As the temperature rises to approximately 260 degrees C, this phase transitions predominantly into Pt₂Si. At approximately 360 degrees C, the PtSi phase starts to form. The conversion of Pt₂Si to PtSi may alter the mechanical boundary condition and mass distribution at the electrode-silicon interface, which in turn may alter the acoustic velocity of the resonator body, producing a shift in resonant frequency and a change in quality factor. In some examples, both silicide phases may be present at the interface following the annealing process, depending on the temperature profile and thermal budget applied.

In some examples, the bottom electrode may comprise gold (Au). Gold exhibits significant interdiffusion with silicon at elevated temperatures. At a first, lower temperature regime, gold atoms may begin to diffuse into the silicon substrate material at a controlled rate, driven by the concentration gradient at the gold-silicon interface. At a second, higher temperature regime, the rate of interdiffusion accelerates and gold-silicon interaction compounds begin to form at or near the electrode-substrate interface. At a suitable temperature, an Au—Si eutectic compound forms. The Au—Si eutectic compound is a metal-semiconductor compound within the scope of the compounds described herein, and its formation may alter the mechanical properties of the electrode-substrate interface in a manner analogous to the platinum examples described above. In various examples, the first current may be selected to raise the electrode temperature above the diffusion onset temperature, permitting controlled gold diffusion into the silicon, and the second current may be selected to raise the electrode temperature to or toward the eutectic formation temperature, at which Au—Si compound formation occurs.

In other examples, the bottom electrode may comprise copper (Cu). Copper diffusion into a silicon substrate material may commence at suitable temperatures in thin-film copper-silicon systems at a controlled and relatively low rate. At this first temperature regime, copper atoms diffuse into the silicon substrate material without immediately forming a distinct stoichiometric compound, allowing diffusion to proceed in a controlled manner. At a second, higher temperature regime, the diffused copper and silicon react to form Cu₃Si, a stoichiometric metal silicide and a metal-semiconductor compound within the scope of the compounds described herein. The formation of Cu₃Si at the electrode-substrate interface may alter the mechanical properties of that interface in a manner analogous to the platinum examples described above. In various examples, the first current may be selected to raise the electrode temperature into the diffusion onset range, permitting controlled copper diffusion into the silicon, and the second current may be selected to raise the electrode temperature to a suitable temperature at which Cu₃Si formation occurs.

In further examples, the bottom electrode may comprise aluminum (Al). Aluminum-silicon interdiffusion in thin-film systems may begin at suitable temperatures. At higher suitable temperatures, Al—Si interface compound formation may occur. The Al—Si interface reaction products are metal-semiconductor compounds within the scope of the compounds described herein, and may produce frequency trimming and quality factor effects by a mechanism analogous to the platinum and copper examples described above.

In various examples, an adhesion layer may optionally be disposed between the bottom electrode and the substrate material. In some examples, the adhesion layer may comprise chromium (Cr). In other examples, the adhesion layer may comprise titanium (Ti). In further examples, the adhesion layer may comprise other thin-film adhesion materials used in MEMS fabrication, such as titanium nitride (TiN) or tantalum (Ta). In some examples, the adhesion layer may be sufficiently thin that it does not substantially impede diffusion of the bottom electrode material into the substrate material upon application of the first and second currents.

In some examples, a voltage across the bottom electrode and a current through the bottom electrode may be monitored during application of the first current and during application of the second current. The Joule heating power delivered to the bottom electrode may be calculated from the relationship P=V×I. The total thermal budget delivered to the bottom electrode may be computed as the integral of P over time, to allow control of thermal dosage and to reduce the likelihood of thermal overshoot that could alter the properties of the transducer layer or other structural elements of the resonant MEMS device. In some examples, the monitored power and cumulative thermal budget values may be used to determine when to transition from the first current to the second current, and when to terminate the second current.

In some examples, anchor structures of the resonant MEMS device may reach higher temperatures than the resonator body during application of the first current or the second current, due to resistive heating concentrated in the current path through the anchor structures. This localized temperature profile may concentrate diffusion and metal-semiconductor compound formation reactions in the regions proximate to the anchor structures, while the resonator body remains at a lower temperature. As a non-limiting example, simulation results have indicated that anchor structures of a resonant MEMS device may reach temperatures on the order of approximately 1060 degrees C during current application, while the silicon device layer and the transducer layer may remain below their respective thermal damage thresholds. In examples employing a zinc oxide (ZnO) transducer layer, the ZnO layer may impose a practical upper temperature limit of approximately 600 to 700 degrees C as a device design consideration for selecting current magnitudes and durations.

In some examples, one or more resonance parameters of the resonant MEMS device may be measured prior to applying the first current, to identify an offset between the measured value and a target value. In some such examples, the magnitude, duration, or waveform of the first current and the second current may be selected based on the identified offset. For example, where the relationship between thermal budget and frequency shift has been characterized for a given device geometry and material system, the current magnitude and duration may be selected to deliver a thermal budget expected to produce a frequency shift of approximately the magnitude of the identified offset. In some examples, such a selection may be made using a lookup table or a predictive model derived from prior characterization data for the device type.

In various examples, the localized annealing process may be incorporated into a deliberate fabrication strategy in which resonant MEMS devices are designed and manufactured with a resonant frequency that is intentionally set below a target operating frequency. Because the localized annealing process shifts resonant frequency in a consistent upward direction, attributable to the increase in Young's modulus that accompanies metal-semiconductor compound formation (e.g., silicides or other compounds) and the associated increase in stiffness of the resonator structure, the direction of frequency shift available through annealing is predictable and unidirectional. A resonator fabricated below its target operating frequency may therefore be trimmed upward toward that target through the application of one or more annealing runs, without risk of overshooting in the wrong direction. In various examples, the pre-trim resonant frequency of each device may be measured at the probe station following fabrication, and the frequency offset between the measured pre-trim frequency and the target operating frequency may be determined for each device individually. An annealing recipe specifying applied current, duration, and total energy dosage may then be selected or calculated to produce a frequency shift of approximately the magnitude of the measured offset, based on a lookup table or predictive model derived from prior characterization data for the device geometry and electrode stack. In various examples, this annealing recipe may be applied in a single run, with the post-anneal frequency measured afterward to verify that the resonance evaluation condition has been satisfied. This single-run approach may be used where the relationship between thermal budget and frequency shift has been sufficiently characterized for the device type to allow reliable single-step targeting.

In various examples where greater precision is desired, or where device-to-device variability in the frequency-shift response has not been fully characterized, an iterative approach may be used in place of or in addition to the single-run approach. In the iterative approach, a first annealing run of a selected duration and power level may be applied, and the resonant frequency may be measured after the device has cooled to ambient temperature. If the measured frequency has not yet reached the target operating frequency, a further annealing run may be applied, and the measuring and re-annealing steps may be repeated until the resonance evaluation condition is satisfied. In various examples, because the frequency drift produced by each successive run at a fixed power level may follow a substantially linear and cumulative relationship with total applied thermal budget, the remaining number of runs or remaining total energy dosage to reach the target frequency may be estimated after one or more initial runs, allowing the iterative process to converge efficiently. In various examples, the fixed-budget cumulative approach, in which successive runs at a consistent power level are applied until a target total energy dosage is reached, and the extrapolative approach, in which data from a small number of characterized run durations is used to predict the outcome at intermediate durations, may be used together within the same trimming workflow. Both the single-run and iterative approaches described above may be implemented in an automated probing system without per-device operator intervention, as described elsewhere herein.

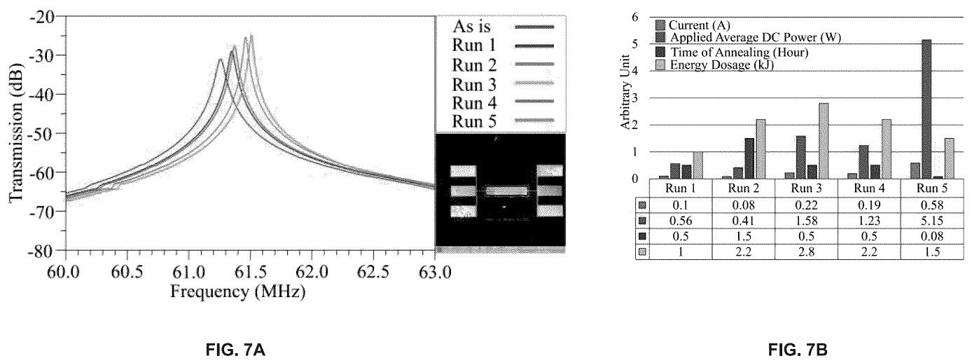

Working Example: Iterative Localized Annealing of a Rectangular-Plate Resonator. The following working example demonstrates the iterative trimming approach described above. A ZnO piezoelectric thin-film piezoelectric-on-silicon (TPoS) rectangular-plate resonator having a Cr/Pt bottom electrode on a silicon device layer was subjected to five successive localized annealing runs. Before the first run, the resonant frequency and transmission response of the device were measured using a vector network analyzer connected to the functional contacts of the device. The measured pre-anneal (“as is”) transmission response is shown in FIG. 7A.

In Run 1, a DC current of 0.1 A was applied to the bottom electrode of the resonator, delivering an applied average DC power of 0.56 W for a duration of 0.5 hours, corresponding to a cumulative energy dosage of 1 kJ. After the device cooled to ambient temperature, the resonant frequency and transmission response were measured. In Run 2, a DC current of 0.08 A was applied, delivering an applied average DC power of 0.41 W for a duration of 1.5 hours, corresponding to a cumulative energy dosage of 2.2 kJ. The resonant frequency and transmission response were again measured after cooling. The annealing parameters for each run are summarized in FIG. 7B.

In Run 3, a DC current of 0.22 A was applied at an applied average DC power of 1.58 W for a duration of 0.5 hours, corresponding to a cumulative energy dosage of 2.8 kJ. In Run 4, a DC current of 0.19 A was applied at an applied average DC power of 1.23 W for a duration of 0.5 hours, corresponding to a cumulative energy dosage of 2.2 kJ. In Run 5, a DC current of 0.58 A was applied at an applied average DC power of 5.15 W for a duration of 0.08 hours (approximately 4.8 minutes), corresponding to a cumulative energy dosage of 1.5 kJ. After each run, the device was allowed to cool to ambient temperature and the resonant frequency and transmission response were measured before the next run was initiated.

As shown in FIG. 7A, each successive annealing run produced a consistent upward shift in the resonant frequency of the device, and the transmission response showed progressive improvement in signal strength across the five runs. The cumulative frequency shift increased with each additional run, and the quality factor (Q) of the device increased progressively across the sequence of runs. The working example confirmed that the iterative application of localized annealing runs at varied power levels and durations produced cumulative and consistent frequency trimming and Q enhancement in the rectangular-plate resonator. The varied annealing parameters across the five runs, as tabulated in FIG. 7B, demonstrated that the trimming process accommodated different combinations of applied current, power, and duration while producing a consistent directional frequency shift and Q improvement at each step.

The diffusion behavior and compound formation characteristics of metal-semiconductor pairs suitable for use in resonant MEMS device electrodes may be characterized by persons of ordinary skill in the art using standard analytical techniques, including without limitation transmission electron microscopy (TEM), energy-dispersive X-ray spectroscopy (EDS), and differential scanning calorimetry (DSC). Relevant temperature thresholds for diffusion and compound formation may be determined experimentally or from established materials data available in the art.

In various instances, the localized annealing techniques described herein may provide an efficient approach to locally annealing devices through the application of a current. After performing initial testing to determine a suitable energy dosage, impact area, and current amount, this technique may allow for controlled resonance shifting of such devices and may be applicable to devices of varying composition.

In various examples, the methods described herein may be performed on a resonant MEMS device prior to dicing of the wafer on which the device is fabricated. In some such examples, a plurality of resonant MEMS devices may be present on a single wafer simultaneously, forming an array of resonant MEMS devices on the wafer. The localized annealing process may be applied to each device in the array individually, for example by selectively applying the first and second currents to each device through its respective functional contacts, without disturbing adjacent devices on the wafer. In this way, the frequency and quality factor of each device in the array may be individually trimmed to a target resonance evaluation condition before the wafer is diced into individual dies. Performing frequency trimming at the wafer level before dicing may reduce handling complexity and enable parallel testing and trimming workflows for high-volume MEMS manufacturing.

In various examples, any of the methods, processes, operations, or steps described herein may be performed, controlled, or coordinated in whole or in part by one or more computing devices executing instructions stored on one or more non-transitory computer-readable media. As used herein, a “non-transitory computer-readable medium” refers to any tangible medium capable of storing instructions that, when executed by one or more processors, cause the one or more processors to perform one or more of the operations described herein, and includes without limitation read-only memory (ROM), random-access memory (RAM), flash memory, electrically erasable programmable read-only memory (EEPROM), magnetic disk storage, optical disk storage, solid-state storage devices, field-programmable gate arrays (FPGAs), application-specific integrated circuits (ASICs), or other suitable storage media. The one or more processors may comprise a general-purpose microprocessor, a digital signal processor (DSP), a microcontroller, a reduced instruction set computing (RISC) processor, or other suitable processing hardware, and may be disposed locally at the equipment performing the described methods or remotely and communicatively coupled thereto via a wired or wireless communication link. In various examples, the instructions stored on the non-transitory computer-readable medium may cause the one or more processors to control one or more of: an applied current magnitude, an applied current duration, a current waveform profile, a power level, a cumulative energy dosage, a duty cycle of a pulsed current, a transition between a first current and a second current, or a termination condition for an annealing run. In various examples, the instructions may further cause the one or more processors to receive measurement data from one or more instruments (e.g., a vector network analyzer, an impedance analyzer, a source meter, a thermocouple, an infrared microscope, or other suitable measurement equipment), to compare the received measurement data against a resonance evaluation condition, and to determine whether to initiate, continue, modify, or terminate an annealing cycle based on the comparison. In various examples, the instructions may cause the one or more processors to execute a closed-loop trimming routine in which the one or more processors iteratively apply an annealing run, receive post-anneal measurement data, evaluate the measurement data against the resonance evaluation condition, and apply a further annealing run if the resonance evaluation condition has not been satisfied, without per-device operator intervention. In various examples, the instructions may cause the one or more processors to select an annealing recipe from a lookup table or to compute an annealing recipe using a predictive model, based on a measured pre-trim frequency offset from a target frequency. In various examples, the computing device may comprise a personal computer, an embedded controller, a programmable logic controller (PLC), a server, or other suitable computing platform, and may include one or more input/output interfaces for communicating with the measurement and current-delivery equipment described herein. Nothing in this disclosure limits the described methods to execution by any particular type of processor, computing architecture, or programming language.

Those skilled in the art will recognize that the above disclosure has been described in connection with particular instances and examples, and that numerous other instances, examples, uses, modifications and departures from the instances, examples and uses are intended to be encompassed by the claims attached hereto. The entire disclosure of each patent and publication cited herein is incorporated by reference, as if each such patent or publication were individually incorporated by reference herein. Various features and advantages of the above disclosure are set forth in the following claims.

What is claimed is:

1. A method comprising:
applying a first current to a bottom electrode underneath a transducer layer of a MEMS device, the bottom electrode overlying a substrate material, to heat the bottom electrode to above a first temperature threshold at which the bottom electrode material diffuses into the substrate material; and
after applying the first current, applying a second current to the bottom electrode to heat the bottom electrode to above a second temperature threshold, higher than the first temperature threshold, at which a metal-semiconductor compound forms between the bottom electrode material and the substrate material.

2. The method of claim 1, further comprising:
during a testing operation, measuring a resonance parameter of the MEMS device after applying the second current; and
applying a third current to the bottom electrode to heat the bottom electrode to above the first temperature threshold, and applying a fourth current to the bottom electrode after applying the third current to heat the bottom electrode to above the second temperature threshold.

3. The method of claim 2, further comprising:
repeating the measuring and the applying of the third and fourth currents until the resonance parameter satisfies a resonance evaluation condition.

4. The method of claim 3, wherein the resonance parameter is one or more of: a quality factor (Q) of the MEMS device, a center frequency of the MEMS device, a motional resistance of the MEMS device, or an insertion loss of the MEMS device.

5. The method of claim 1, wherein the substrate material comprises silicon, and the bottom electrode material comprises platinum.

6. The method of claim 5, wherein the metal-semiconductor compound comprises PtSi, wherein the first temperature threshold is above a Pt₂Si formation temperature at which Pt₂Si forms between the bottom electrode material and the substrate material, and wherein the second temperature threshold is above a PtSi formation temperature at which Pt₂Si converts to PtSi.

7. The method of claim 5, wherein the substrate material is a silicon device layer of a silicon-on-insulator (SOI) wafer, the SOI wafer further comprising a buried oxide layer beneath the silicon device layer and a silicon handle wafer beneath the buried oxide layer.

8. The method of claim 1, wherein the bottom electrode material comprises one or more of: platinum (Pt), gold (Au), copper (Cu), or aluminum (Al).

9. The method of claim 1, wherein the metal-semiconductor compound is a silicide.

10. The method of claim 9, wherein the bottom electrode material comprises platinum (Pt) or copper (Cu).

11. The method of claim 1, wherein an adhesion layer is disposed between the bottom electrode and the substrate material.

12. The method of claim 11, wherein the adhesion layer comprises chromium (Cr) or titanium (Ti).

13. The method of claim 1, wherein the transducer layer comprises a piezoelectric material.

14. The method of claim 1, wherein applying the first current and applying the second current comprise applying a continuously increasing current that causes the temperature of the bottom electrode to rise above the first temperature threshold and subsequently above the second temperature threshold.

15. The method of claim 1, wherein applying the first current and applying the second current comprise applying a pulsed current in a plurality of duty cycles to cumulatively drive the temperature of the bottom electrode above the first temperature threshold and subsequently above the second temperature threshold.

16. The method of claim 1, further comprising:
monitoring a voltage across and a current through the bottom electrode during application of the first current and during application of the second current; and
calculating a Joule heating power delivered to the bottom electrode from the monitored voltage and current.

17. The method of claim 1, further comprising applying the first current and the second current via functional contacts of the MEMS device.

18. The method of claim 1, wherein the first current and the second current are each direct currents (DC).

19. The method of claim 1, further comprising measuring a resonance parameter of the MEMS device prior to applying the first current to identify an offset from a target value, and selecting a magnitude and duration of the first current and the second current based on the identified offset.

20. The method of claim 1, wherein the applying of the first current and the second current is performed prior to dicing of a wafer on which the MEMS device is fabricated.
